(19) United States
(12) Patent Application Publication
(10) Pub. No.: US 2004/0165659 A1
(43) Pub. Date: Aug. 26, 2004

(54) Apparatus and method of equalizing channel in digital broadcasting receiver

(75) Inventor: Dong-won Kim, Seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 10/727,994

(22) Filed: Dec. 5, 2003

(30) Foreign Application Priority Data
Dec. 13, 2002 (KR) 2002-79744

(51) Int. Cl. H03K 5/159; H04B 1/10

(52) U.S. Cl. 375/232; 375/350

(57) ABSTRACT

An apparatus and a method for performing channel equalization in a digital broadcasting receiver based on a ghost level is disclosed. The apparatus includes a filtering unit and an equalization amplitude control unit. The filtering unit filters a received broadcasting signal and outputs an equalization channel output signal. If a ghost is included in the received broadcasting signal, the equalization amplitude control unit controls an equalization coverage area of the received broadcasting signal by controlling a filtering coefficient of the filtering unit based on the level of ghost.

### CROSS REFERENCE TO RELATED APPLICATION

This application claims the priority of Korean Patent Application No. 2002-79744, filed on 13 Dec. 2002, in the Korean Intellectual Property Office, the disclosure of which is hereby incorporated by reference in its entirety.

### BACKGROUND OF THE INVENTION

1. Field of the Invention

Apparatuses and methods consistent with the present invention relate to equalizing a channel in a digital broadcasting receiver, and more particularly, to an apparatus and a method of equalizing a channel in a digital broadcasting receiver, thereby preventing the performance of a digital broadcasting receiver from degrading by a ghost.

2. Description of the Related Art

In general, digital broadcasting receivers use free space as their physical channels. Since the transmission path of a digital broadcasting signal changes with climate changes in the air, clouds, or troposphere, affects of the sun's changes, geographical features such as mountains, cliffs, or the ground, momentary movements of a mobile object in an outdoor environment or/and an indoor environment, caused due to movements of cars or airplanes and the use of electronic appliances, the digital broadcasting signal is received by the digital broadcasting receiver through multiple transmission paths. As a result, ghosting occurs when the same digital broadcasting signal is received at different time.

The digital broadcasting signal received by the digital broadcasting receiver is distorted due to a ghost. Thus, a screen is entirely or partially broken. In the worst-case scenario, images may not be displayed at all. As such, a conventional digital broadcasting receiver cancels the ghost using a channel equalizer to provide good performance even when the ghost occurs.

The ghost can be classified into near ghosts, occurring subject to indoor environments, and long ghosts, occurring subject to outdoor environments. The near ghost occurs in a time range ranging from −0.3 μs to +0.3 μs. The long ghosts occur in a time range of more than +0.3 μs. Consequently, in indoor environments, the near ghosts have a level higher than the long ghosts.

However, as shown in FIG. 1, the channel equalizer used in the conventional digital broadcasting receiver is configured to have a fixed equalization coverage area or a fixed equalization amplitude in the time range and a phase range, irrespective of possible levels of the long ghosts and the near ghosts. For example, the time range ranges from −7.5 μs to +46 μs, and the phase range ranges from 0° to 359°.

Accordingly, if a level of the near ghost does not fall within the equalization coverage area of the channel equalizer in the indoor environments, the channel equalizer cannot completely cancel the near ghost. Thus, the image may be broken or not displayed at all.

### SUMMARY OF THE INVENTION

The present invention provides an apparatus and a method which equalize a channel in a digital receiver in consideration of the ghost level of a received signal in a time range and a phase range.

The present invention also provides an apparatus and a method which equalize a channel in a digital broadcasting receiver, which vary a channel equalization amplitude of a received broadcasting signal in consideration of the ghost level of the received broadcasting signal.

The present invention also provides an apparatus and a method which equalize a channel in a digital broadcasting receiver, which completely cancel near ghosts in indoor environments.

According to one aspect of the present invention, there is provided a channel equalization apparatus in a digital broadcast receiver. The apparatus comprises a filtering unit and an equalization amplitude control unit. The filtering unit filters a received broadcasting signal and outputs a channel equalization output signal. The equalization amplitude control unit controls an equalization coverage area of the received broadcasting signal by controlling a filtering coefficient of the filtering unit based on the level of ghost, if a ghost is included in the received broadcasting signal.

According to another aspect of the present invention, there is provided a channel equalization method in a digital broadcast receiver. The method comprises detecting a ghost from a received broadcasting signal, detecting the level of the ghost, and controlling an equalization coverage area of the received broadcasting signal based on the detected level of the ghost and performing channel equalization for the received broadcasting signal.

### BRIEF DESCRIPTION OF THE DRAWINGS

The above and other aspects and advantages of the present invention will become more apparent by describing in detail an exemplary embodiment thereof with reference to the attached drawings in which:

FIG. 1 shows the relationship between an equalization coverage area of a conventional channel equalizer and a near ghost occurring out of the range of the equalization coverage area;

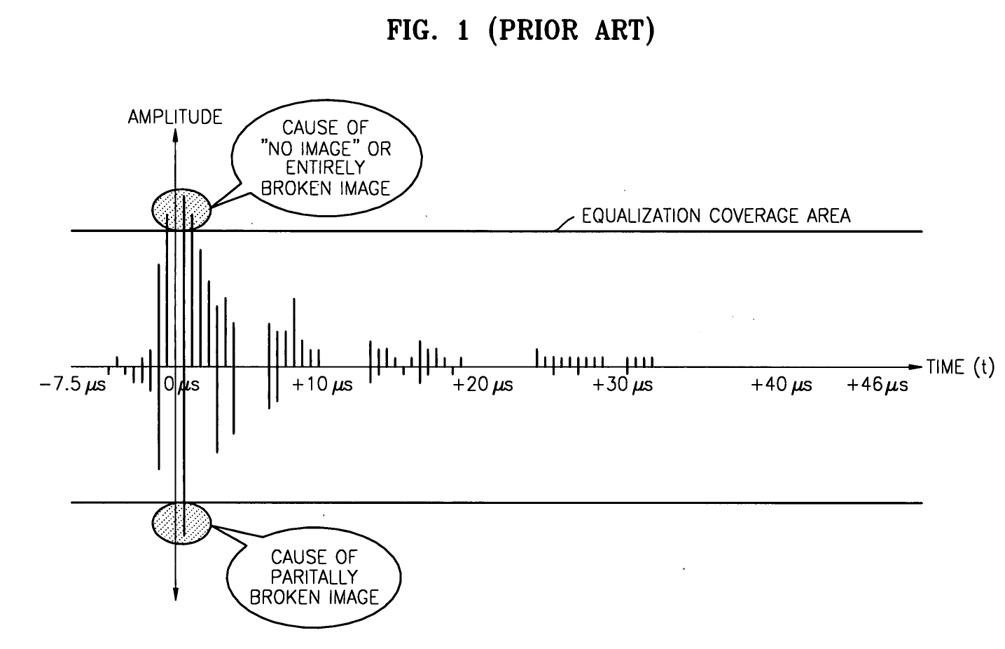

FIG. 2 is a functional block diagram of an apparatus which equalizes a channel in a digital broadcasting receiver, according to the present invention;

FIG. 3 shows the relationship between an equalization coverage area and a ghost in channel equalization according to the present invention; and

FIG. 4 is a flowchart describing a method of equalizing a channel in a digital broadcasting receiver, according to the present invention.

### DETAILED DESCRIPTION OF THE INVENTION

The present invention will now be described more fully with reference to the accompanying drawings, in which an exemplary embodiment of the invention is shown.

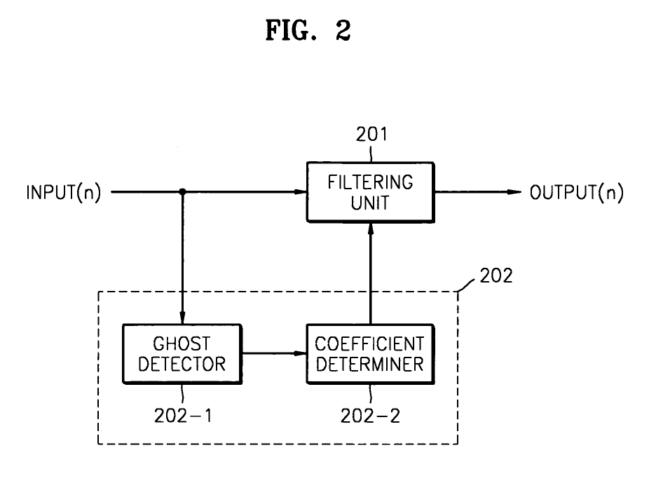

FIG. 2 is a functional block diagram of a channel equalization in a digital broadcasting receiver, according to the present invention. Referring to FIG. 2, the channel equalization includes a filtering unit 201 and an equalization amplitude control unit 202.

The filtering unit 201 filters an input signal “input (n)” at a time “n” and outputs a channel equalization output signal “output (n)”. The input signal “input (n)” is a digital broadcasting signal that has been converted by an analog-to-digital converter (ADC) (not shown) included in the digital broadcasting receiver.

The equalization amplitude control unit 202 includes a ghost detector 202-1 and a coefficient determiner 202-2.

Once the input signal “input (n)” is input, the ghost detector 202-1 determines whether a ghost is present in the input signal “input (n)”. If a ghost is detected, the ghost detector 202-1 detects the level of the detected ghost and determines whether the detected ghost is a near ghost or a long ghost based on the time range and phase range of the detected ghost.

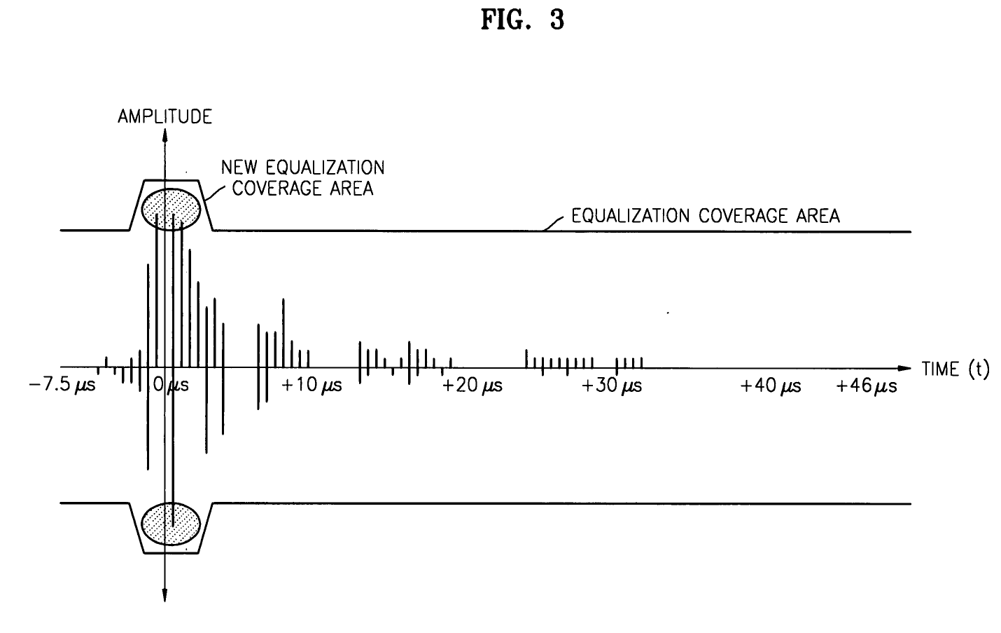

That is, the ghost detector 202-1 identifies a main signal within the input signal “input (n)”. The main signal corresponds to an actual broadcasting signal and “0 μs” on the time axis of a graph of FIG. 3, which shows an example of an equalization coverage area or an equalization amplitude. The ghost detector 202-1 detects the main signal using a time symbol.

If the broadcasting signal is present in near time range and phase range based on the detected main signal, the ghost detector 202-1 recognizes that the ghost is present in the input signal “input (n)”. If a DC level is detected in the time range and the phase range near the main signal, the ghost detector 202-1 recognizes that the broadcasting signal is present in the near time range and phase range based on the detected main signal.

If the broadcasting signal is present in the time range and the phase range near the main signal and the time range ranges from −0.3 μs to +0.3 μs, the ghost detector 202-1 recognizes the detected ghost as a near ghost type. In contrast, if the broadcasting signal is present in a time range of more than +0.3 μs or less than −0.3 μs, the ghost detector 202-1 does not recognize the detected ghost as a near ghost type. Specially, if the detected ghost is present in a time range of more than +0.3 μs, the ghost detector 202-1 recognizes the detected ghost as a long ghost type. The long ghost is a remote ghost based on the detected main signal.

Thereafter, the ghost detector 202-1 detects the DC level of the detected ghost. The ghost detector 202-1 provides the DC level of the detected ghost and the type information of the detected ghost, e.g., an adjacent ghost or a remote ghost, to the coefficient determiner 202-2.

The coefficient determiner 202-2 determines a filtering coefficient which is provided to the filtering unit 201, based on the DC level of and the type of the detected ghost. If the detected ghost is a near ghost and the DC level does not fall within the equalization coverage area, the coefficient determiner 202-2 determines the filtering coefficient, so that the filtering unit 201 has an equalization amplitude to accept the DC level of the detected ghost and performs the channel equalization for the input (n).

In this case, the coefficient determiner 202-2 determines a large coefficient to set a filtering large equalization amplitude. In other words, the coefficient determiner 202-2 determines the filtering coefficient to set a large filtering equalization coverage area, as shown in FIG. 3. The coefficient determiner 202-2 can determine the coefficient such that a newly set equalization coverage area, as shown in FIG. 3, is applied to the time range and phase range ranging from −0.3 μs to +0.3 μs. The coefficient determiner 202-2 can determine the filtering coefficient such that different equalization coverage areas are applied to the time range and phase range ranging from −0.3 μs to +0.3 μs by the detected ghost level.

Additionally, the coefficient determiner 202-2 can determine the filtering coefficient such that the existing equalization coverage area is applied to the time range and the phase range outside the time range and the phase range where the near ghost is present, in a manner similar to FIG. 3. If the ghost level detected in time range and phase range outside the near ghost area is not included in the existing equalization coverage area, the coefficient determiner 202-2 determines the filtering coefficient greater than that of the existing equalization coverage area, such that the equalization coverage area becomes greater than the existing equalization coverage area. A plurality of filtering coefficients available for filtering coefficient decision is previously stored in the coefficient determiner 202-2.

The filtering unit 201 outputs the channel equalization output signal “output (n)” that is obtained by equalizing a channel of the input signal “input (n)” based on the filtering coefficient provided by the coefficient determiner 202-2.

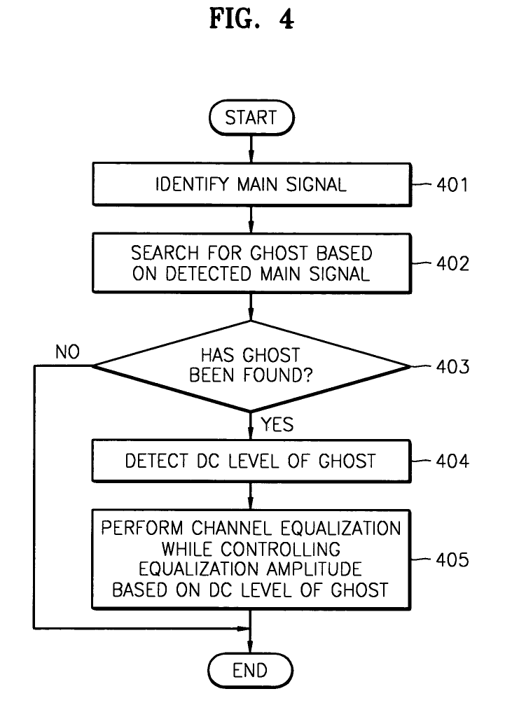

FIG. 4 is a flowchart showing a method of equalizing a channel in a digital broadcasting receiver, according to the present invention.

After an input signal “input (n)” that is converted into a digital signal is received, a main signal is identified in the received signal in step 401. The main signal is an actual broadcasting signal based on a basis of time, as aforesaid with reference to FIG. 2.

Then, in step 402, a ghost is searched for based on the detected main signal. In other words, as mentioned in the description of the ghost detector 202-1 of FIG. 2, a ghost is detected based on a basis of time.

In step 403, it is determined whether a ghost has been found. If a ghost has been found, the DC level of the ghost is detected in step 404. In step 405, the channel equalization of the input signal “input (n)” is performed while controlling the equalization amplitude of the input signal “input (n)” based on the detected DC level of the ghost. In other words, if the existing equalization coverage area can cover the detected DC level of ghost, channel equalization filtering for the input signal “input(n)” is performed using the filtering coefficient corresponding to the existing equalization coverage area. In contrast, if the existing equalization coverage area does not cover the detected DC level of the ghost, an equalization coverage area is newly set based on the detected DC level of the ghost. In other words, the filtering coefficient is determined to increase or extend the existing equalization coverage area. And then the channel equalization filtering for the input signal “input(n)” is performed.

In FIG. 4, the equalization coverage area is controlled based on the detected DC level of the ghost, irrespective of the type of ghost, e.g., a near ghost or a long ghost. However, it is also possible to determine whether a near ghost is detected, and, if so, to set the time range ranging from −0.3 μs to +0.3 μs and the phase range as a new equalization coverage area, as shown in FIG. 3.

As described above, it is possible to completely cancel a ghost included in the received broadcasting signal and prevent performance of a digital broadcast receiver from degrading due to a ghost, by setting the equalization amplitude or the equalization coverage area based on the DC level of a ghost included in the received broadcasting signal.

In particular, since a near ghost caused by an indoor environment can be completely cancelled, performance of the digital broadcasting receiver in an indoor environment can be improved.

While the present invention has been particularly shown and described with reference to an exemplary embodiment thereof, it will be understood by those of ordinary skill in the art that various changes in form and details may be made therein without departing from the spirit and scope of the invention as defined by the appended claims and their equivalents.

What is claimed is:

1. A channel equalization apparatus in a digital receiver, the apparatus comprising:
a filter filtering a received signal and outputting a channel equalization output signal; and
an equalization amplitude control unit controlling an equalization coverage area of the received signal by controlling a filtering coefficient of the filter based on a level of a ghost, if the ghost is included in the received signal.

2. The apparatus of claim 1, wherein the equalization amplitude control unit comprises:
a detector detecting the level of the ghost and outputting a determination result; and
a coefficient determiner determining the filtering coefficient based on the level of the ghost detected by the detector and providing the filtering coefficient to the filter.

3. The apparatus of claim 2, wherein the detector determines whether the ghost is a near ghost and the coefficient determiner determines the filtering coefficient by referring to the determination result of the detector.

4. The apparatus of claim 3, wherein if the ghost is the near ghost and the equalization coverage area is required to change, the coefficient determiner provides the filtering coefficient to the filter, such that the filtering coefficient is applied to a time range and a phase range of the near ghost.

5. A channel equalization method in a digital receiver, the method comprising;
detecting a ghost from a received signal;
detecting a level of the ghost as a detected level of the ghost; and
controlling an equalization coverage area of the received signal based on the detected level of the ghost and performing channel equalization for the received signal.

6. The method of claim 5 further comprising determining whether the detected ghost is a near ghost, wherein if the detected ghost is the near ghost, performing channel equalization further comprises applying the equalization coverage area based on the detected level of the ghost to an equalization coverage area of the near ghost.

7. The apparatus of claim 4, wherein the digital receiver is a digital broadcast receiver and the received signal is a received broadcasting signal.

8. The method of claim 6, wherein the digital receiver is a digital broadcast receiver and the received signal is a received broadcasting signal.

9. A channel equalization apparatus in a digital receiver, the apparatus comprising:
means for filtering a received signal and outputting a channel equalization output signal; and
means for controlling an equalization coverage area of the received signal by controlling a filtering coefficient of the means for filtering based on a level of a ghost, if the ghost is included in the received signal.

10. The apparatus of claim 9, wherein the means for controlling the equalization coverage area comprises:
means for detecting the level of the ghost and outputting a determination result; and
means for determining the filtering coefficient based on the level of the ghost detected by the means for detecting and providing the filtering coefficient to the means for filtering.
